(19) United States
(12) Patent Application Publication
(10) Pub. No.: US 2023/0411117 A1
(43) Pub. Date: Dec. 21, 2023

(54) ANTENNA MEMBER AND APPARATUS AND METHOD FOR TREATING SUBSTRATE

(71) Applicant: SEMES CO., LTD., Chungcheongnam-do (KR)

(72) Inventors: Yoon Seok CHOI, Chungcheongnam-do (KR); Sang Jeong LEE, Chungcheongnam-do (KR); Jae Won SHIN, Chungcheongnam-do (KR); Hyun Woo JO, Chungcheongnam-do (KR); Jong Won PARK, Chungcheongnam-do (KR)

(21) Appl. No.: 18/097,232

(22) Filed: Jan. 14, 2023

(30) Foreign Application Priority Data
Jun. 16, 2022 (KR) 10-2022-0073223

(51) Int. Cl. H01J 37/32

(52) U.S. Cl. CPC H01J 37/3211; H01J 37/3244; H01J 37/32119

(57) ABSTRACT

An antenna member includes a first coil and a second coil that are rotationally symmetrical with each other, wherein the first coil includes a first supply terminal to which current is applied, a first ground terminal connected to a ground, and a first shunt capacitor shunted between the first supply terminal and the first ground terminal, the second coil includes a second supply terminal to which current is applied, a second ground terminal connected to the ground, and a second shunt capacitor shunted between the second supply terminal and the second ground terminal, the first coil includes an arc-shaped first portion and an arc-shaped second portion, and the first portion and the second portion form a one-turn winding as a whole, the second coil includes an arc-shaped first portion and an arc-shaped second portion, and the first portion and the second portion form a one-turn winding as a whole, the second portion has a height lower than a height of the first portion, the second portion of the second coil is disposed below the first portion of the first coil, and the second portion of the first coil is disposed below the first portion of the second coil.

### CROSS-REFERENCE TO RELATED APPLICATION(S)

This application claims benefit of priority to Korean Patent Application No. 10-2022-0073223 filed on Jun. 16, 2022 in the Korean Intellectual Property Office, the disclosure of which is incorporated herein by reference in its entirety.

### BACKGROUND

### 1. Field

The present disclosure relates to a substrate treatment apparatus using plasma, an antenna member provided thereto, and a substrate treating method.

### 2. Description of Related Art

A substrate treatment apparatus performs a deposition, etching, or cleaning process on a substrate using plasma. Apparatuses for treating a substrate using plasma include a capacitively coupled plasma (CCP) type apparatus generating plasma using an electric field and an inductively coupled plasma (ICP) type apparatus generating plasma using a magnetic field. The ICP type apparatus uses an antenna member as a plasma source. The ICP type apparatus generates a magnetic field by allowing current to flow through an antenna member.

According to an antenna member of the related art, a potential applied to the antenna member becomes an undesirable CCP source, causing damage (such damage is referred to as ‘CCP damage’) to a component of an apparatus, such as a window. In a portion of the antenna member having a high potential is disposed to be close to the window, the CCP damage is larger, and since a distribution of a generated magnetic field is not symmetric, plasma uniformity is not good. Therefore, in the related art, the plasma uniformity on a treatment surface of a substrate has been improved by connecting variable capacitors in parallel, but since it is significantly complicated to finely adjust a current flowing through the antenna member with respect to the entire orientation, it is difficult to adjust the intensity of a magnetic field induced in a chamber in detail and there is a limit to voltage distribution.

### SUMMARY

Exemplary embodiments provide an antenna member capable of efficiently performing voltage distribution and finely adjusting a current flowing through the antenna member, and a substrate treatment apparatus including the same and a method thereof.

According to an aspect of the present disclosure, an antenna member includes a first coil and a second coil that are rotationally symmetrical with each other, wherein the first coil includes a first supply terminal to which current is applied, a first ground terminal connected to a ground, and a first shunt capacitor shunted between the first supply terminal and the first ground terminal, the second coil includes a second supply terminal to which current is applied, a second ground terminal connected to the ground, and a second shunt capacitor shunted between the second supply terminal and the second ground terminal, the first coil includes an arc-shaped first portion and an arc-shaped second portion, and the first portion and the second portion form a one-turn winding as a whole, the second coil includes an arc-shaped first portion and an arc-shaped second portion, and the first portion and the second portion form a one-turn winding as a whole, the second portion has a height lower than a height of the first portion, the second portion of the second coil is disposed below the first portion of the first coil, and the second portion of the first coil is disposed below the first portion of the second coil.

According to another aspect of the present disclosure, a substrate treatment apparatus includes: a chamber providing a treatment space; a chuck member provided in the treatment space to support a substrate; a window disposed above the chuck member; and an antenna member disposed above the window, wherein the antenna member includes: a first coil and a second coil that are rotationally symmetrical with each other, wherein the first coil includes a first supply terminal to which current is applied, a first ground terminal connected to a ground, and a first shunt capacitor shunted between the first supply terminal and the first ground terminal, the second coil includes a second supply terminal to which current is applied, a second ground terminal connected to the ground, and a second shunt capacitor shunted between the second supply terminal and the second ground terminal, the first coil includes an arc-shaped first portion and an arc-shaped second portion, and the first portion and the second portion form a one-turn winding as a whole, the second coil includes an arc-shaped first portion and an arc-shaped second portion, and the first portion and the second portion form a one-turn winding as a whole, the second portion has a height lower than a height of the first portion, the second portion of the second coil is disposed below the first portion of the first coil, and the second portion of the first coil is disposed below the first portion of the second coil.

According to another aspect of the present disclosure, a substrate treating method performed by the substrate treatment apparatus described above includes: adjusting a leftward current or a rightward current flowing through the antenna member according to capacitance of the first shunt capacitor or the second shunt capacitor, wherein the adjusting includes at least one of: an operation in which a ratio of the first shunt capacitor and the second shunt capacitor is the same so that there is no change in the leftward current or the rightward current; an operation in which there is no change in the first shunt capacitor, and a magnitude of capacitance of the second shunt capacitor is adjusted to be greater than a magnitude of capacitance of the first shunt capacitor to fix the rightward current and adjust only the magnitude of the leftward current; and an operation in which there is no change in the second shunt capacitor, and the magnitude of capacitance of the first shunt capacitor is adjusted to be greater than the magnitude of capacitance of the second shunt capacitor to fix the leftward current and adjust only the magnitude of the rightward current.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 schematically illustrates a substrate treatment apparatus according to an exemplary embodiment in the present disclosure;

FIG. 2 is a perspective view of an antenna member according to an exemplary embodiment in the present disclosure;

FIG. 3 is a diagram illustrating a usage aspect of an antenna member according to an exemplary embodiment in the present disclosure, in which a first coil and a second coil are disassembled;

FIG. 4 illustrates an equivalent circuit diagram of an antenna member according to an exemplary embodiment in the present disclosure;

FIG. 5 illustrates current according to each point of an antenna member according to an exemplary embodiment in the present disclosure;

FIG. 6 is a diagram illustrating current according to each point of an antenna member according to an exemplary embodiment in the present disclosure, in which a first coil and a second coil are disassembled;

FIG. 7 is a diagram illustrating a leftward current and a rightward current of an antenna member obtained by adding currents of a first coil and a second coil illustrated in FIG. 6; and

FIG. 8 is a flowchart illustrating a substrate treating method of a substrate treatment apparatus including an antenna member according to an exemplary embodiment in the present disclosure.

### DETAILED DESCRIPTION

Hereinafter, exemplary embodiments will be described in detail with reference to the accompanying drawings such that they may be easily practiced by those skilled in the art to which the present disclosure pertains. In describing the present disclosure, if a detailed explanation for a related known function or construction is considered to unnecessarily divert the gist of the present disclosure, such explanation will be omitted but would be understood by those skilled in the art. Also, similar reference numerals are used for the similar parts throughout the specification. In this disclosure, terms, such as “above”, “upper portion”, “upper surface”, “below”, “lower portion”, “lower surface”, “lateral surface”, and the like, are determined based on the drawings, and in actuality, the terms may be changed according to a direction in which a device or an element is disposed.

It will be understood that when an element is referred to as being “connected to” another element, it may be directly connected to the other element or intervening elements may also be present. In contrast, when an element is referred to as being “directly connected to” another element, no intervening elements are present. In addition, unless explicitly described to the contrary, the word “comprise” and variations, such as “comprises” or “comprising,” will be understood to imply the inclusion of stated elements but not the exclusion of any other elements. The present disclosure is not limited by the exemplary embodiments described above and accompanying drawings. The scope of the present disclosure is limited by the appended claims and it may be obvious to those skilled in the art that the present disclosure may be variously substituted, modified, and changed without departing from the scope of the present disclosure described in the claims.

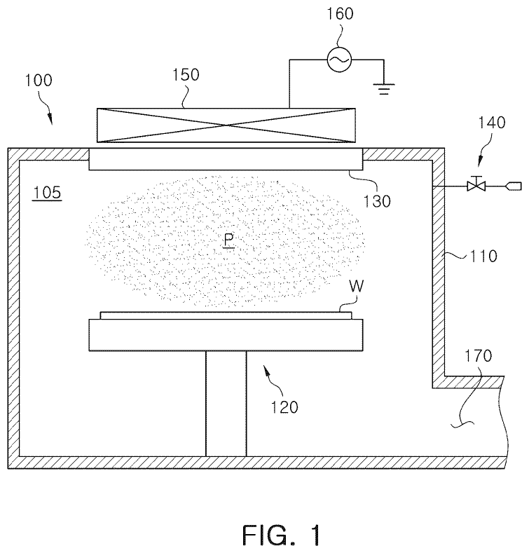

Referring to FIG. 1, a plasma treating apparatus 100 includes a chamber 110, a chuck member 120, a window 130, a gas supply unit 140, an antenna member 150, a power supply unit 160, and an exhaust port 170.

The chamber 110 provides a treatment space 105. In the treatment space 105, a substrate W to be treated by plasma P is located. The chuck member 120 supports a substrate W. The chuck member 120 is disposed within the chamber 110. The substrate W is located on an upper surface of the chuck member 120 and supported by the chuck member 120.

The window 130 is disposed above the chuck member 120. Generally, the window 130 is disposed above the substrate W to be treated. The window 130 is provided as a dielectric material. For example, the window 130 is formed of a quartz material. RF energy is coupled to a source gas through the window 130 to ignite and maintain a suitable plasma for a substrate treatment.

The gas supply unit 140 supplies a source gas for treating the substrate W to the treatment space 105.

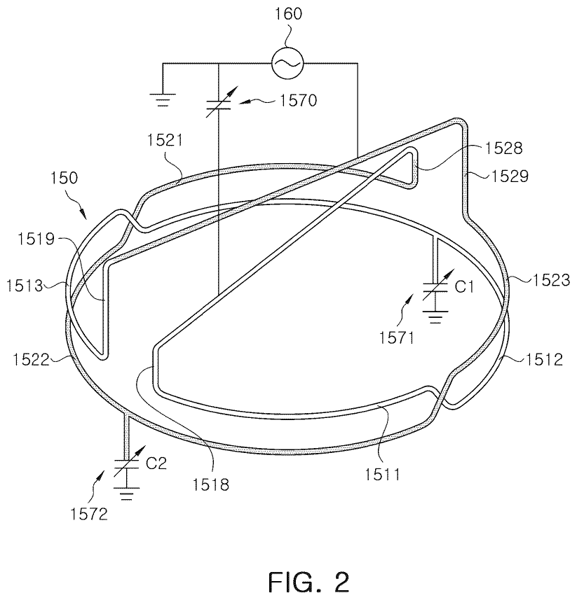

The antenna member 150 is disposed over the dielectric window 130 and is supplied with power by the power supply unit 160. The antenna member 150 forms a magnetic field from the supplied power. The formed magnetic field generates plasma P from the source gas. The antenna member 150 will be described in detail in the description of FIGS. 2 to 6.

The power supply unit 160 applies power to the antenna member 150. Power applied by the power supply unit 160 may be radio frequency (RF) power. When RF power is fed from the power supply unit 160 to the antenna member 150, an inductively coupled plasma may be formed inside the process chamber from a magnetic field generated by the antenna member 150.

Although not illustrated, an impedance matching circuit may be included in a cable to which the power supply unit 160 and the antenna member 150 are connected. The exhaust port 170 is provided below the chamber 110. The exhaust port 170 is connected to a pump (not illustrated). Plasma and residual products generated in the treatment space 105 are discharged externally from the treatment space 105 through the exhaust port 170. A pump (not illustrated) forcibly discharges plasma and residual products generated in the treatment space 105.

Hereinafter, the antenna member 150 will be described with reference to FIGS. 2 to 6.

The antenna member 150 includes a first coil 1510 and a second coil 1520. The first coil 1510 and the second coil 1520 are rotationally symmetrical to each other. In an exemplary embodiment, the first coil 1510 and the second coil 1520 are rotationally symmetrical with each other by 180°.

The first coil 1510 includes a first supply terminal 1519 to which current is applied and a first ground terminal 1518 connected to a ground. The first coil 1510 is provided in a coil shape as one wire. The first supply terminal 1519 is one end of the first coil 1510, and the first ground terminal 1518 is the other end of the first coil 1510. The first supply terminal 1519 and the first ground terminal 1518 are provided to be adjacent to each other.

In addition, the first coil 1510 includes a first shunt capacitor C1 1571 shunted between the first supply terminal 1519 and the first ground terminal 1518.

The first coil 1510 includes first portions 1511 and 1513 and a second portion 1512 having a height lower than that of the first portions 1511 and 1513 when viewed from the side. The first portions 1511 and 1513 and the second portion 1512 are combined with each other to form a one-turn winding as a whole. The first portions 1511 and 1513 include a (1-1)-th portion 1511 and a (1-2)-th portion 1513. In the one-turn winding of the first coil 1510, the (1-1)-th portion 1511 extending from the first ground terminal 1518 is wound to form a center angle of 90° and then lowered in height to extend to the second portion 1512. After the second portion 1512 is wound to form a center angle of 180°, the second portion 1512 is raised in height to extend to the (1-2)-th portion 1513. The (1-2)-th portion 1513 is wound to form a center angle of 90°. The indication of the angles 90° and 180° above means that they are substantially 90° and 180° considering portions in which the height changes, but does not mean that they are mathematically exactly 90° and 180°.

The first supply terminal 1519 of the first coil 1510 may be provided to the first portions 1511 and 1513, and as illustrated in FIG. 2, the first supply terminal 1519 may be provided to the (1-2)-th portion 1513.

The first shunt capacitor 1571 of the first coil 1510 may be provided to the second portion 1512.

The second coil 1520 includes a second supply terminal 1529 to which current is applied and a second ground terminal 1528 connected to a ground. The second coil 1520 is provided in a coil shape as one wire. The second supply terminal 1529 is one end of the second coil 1520, and the second ground terminal 1528 is the other end of the second coil 1520. The second supply terminal 1529 and the second ground terminal 1528 are provided to be adjacent to each other.

In addition, the second coil 1520 includes a second shunt capacitor C2 1572 shunted between the second supply terminal 1529 and the second ground terminal 1528.

The second coil 1520 includes first portions 1521 and 1523 wound once, and a second portion 1522 having a height lower than that of the first portions 1521 and 1523 when viewed from the side. The first portions 1521 and 1523 and the second portion 1522 are combined with each other to form a one-turn winding as a whole. The first portions 1521 and 1523 include a (1-1)-th portion 1521 and a (1-2)-th portion 1523. In the one-turn winding of the second coil 1520, the (1-1)-th portion 1521 extending from the second ground terminal 1528 is wound to form a center angle of 90°, and then lowered in height to extend to the second portion 1522. After the second portion 1522 is wound to form a center angle is 180°, the second portion 1522 is raised in height to extend to the (1-2)-th portion 1523. The (1-2)-th portion 1523 is wound to form a center angle of 90°. The indication of the angles 90° and 180° above means that they are substantially 90° and 180° considering portions in which the height changes, but does not mean that they are mathematically exactly 90° and 180°.

The second supply terminal 1529 of the second coil 1510 may be provided to the first portions 1521 and 1523, and as illustrated in FIG. 2, the second supply terminal 1529 may be provided to the (1-2)-th portion 1523.

The second shunt capacitor 1572 of the second coil 1520 may be provided in the second portion 1522.

The second portion 1522 of the second coil 1520 is disposed below the first portions 1511 and 1513 of the first coil 1510. The second portion 1512 of the first coil 1510 is disposed below the first portions 1521 and 1523 of the second coil 1520.

In an exemplary embodiment, when a first plane and a second plane are sequentially lower planes, the first portions 1511 and 1513 of the first coil 1510 and the first portions 1521 and 1523 of the second coil 1520 are located on the first plane. The second portion 1512 of the first coil 1510 and the second portion 1522 of the second coil 1520 are located on the second plane.

Therefore, the antenna member 150 according to an exemplary embodiment in the present disclosure is a dual inductively coupled plasma (ICP) antenna in which the first coil 1510 and the second coil 1520 are symmetrically arranged and each coil is connected in parallel, and when RF power is supplied by the power supply unit 160, the first coil 1510 and the second coil 1520 may be matched so that current directions thereof are the same.

A variable capacitor 1570 is provided to each of the first ground terminal 1518 and the second ground terminal 1528. The variable capacitor 1570 functions as a balance capacitor. A variable capacitor 1570 adjusts a potential.

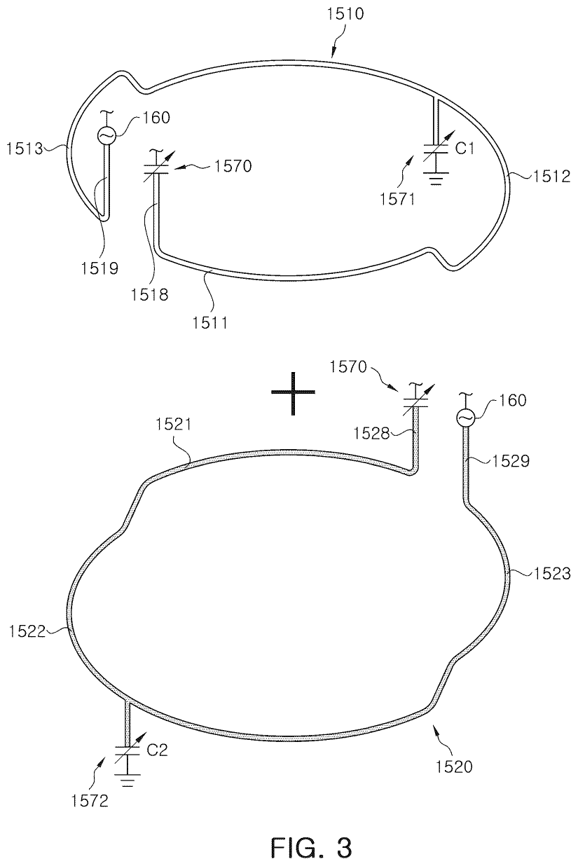

FIG. 3 is a diagram illustrating a usage aspect of the antenna member 150 according to the first exemplary embodiment, in which the first coil 1510 and the second coil 1520 are disassembled.

By way of an example, an RF voltage of 200V is applied to each of the first coil 1510 and the second coil 1520 of the antenna 150. Through the variable capacitor 1570, each of the first coil 1510 and the second coil 1520 is adjusted so that a neutral point (a portion in which the potential is 0V) is located in the center. In an exemplary embodiment, the variable capacitor 1570 is adjusted so that a neutral point of a potential is located in a position of ½ of the length of each of the first coil 1510 and the second coil 1520. A potential at the first supply terminal 1519 and the second supply terminal 1529 may be adjusted to 100V, and a potential at the first ground terminal 1518 and the second ground terminal 1528 may be adjusted to −100V.

When RF voltage is applied to the first coil 1510 and the second coil 1520, the potential applied to a midpoint of the first coil 1510 and the potential applied to a midpoint of the second coil 1520 cancel each other out.

In addition, the first shunt capacitor C1 1571 may be connected to a midpoint of the first coil 1510 and the second shunt capacitor C2 1572 may be connected to a midpoint of the second coil 1520, and the first shunt capacitor 1571 and the second shunt capacitor 1572 may be variable capacitors.

Through the shunt capacitors, a current flowing through the antenna member 150 may be adjusted before and after each of the first shunt capacitor 1571 and the second shunt capacitor 1572.

Through this, plasma uniformity may be adjusted, so that the magnitude of the current flowing through the antenna member 150 becomes the magnitude of the magnetic field induced in the chamber, and thus the plasma uniformity in the chamber may be precisely controlled.

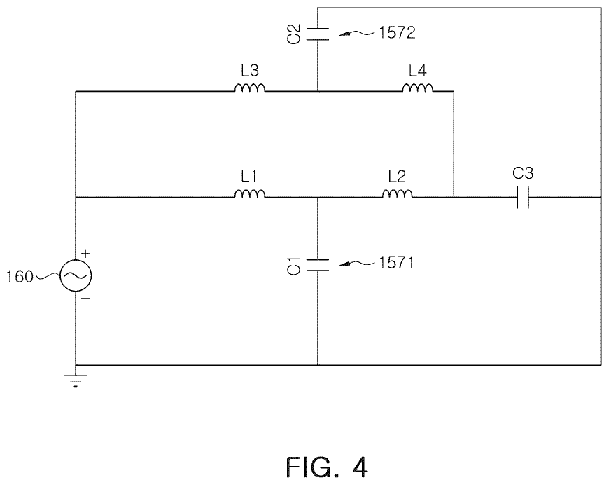

FIG. 4 illustrates an equivalent circuit diagram of the antenna member 150 according to an exemplary embodiment in the present disclosure.

Referring to FIG. 4, an inductor is connected to one end of the power supply unit 160, the first coil 1510 is an equivalent circuit element of inductors L1 and L2, and the second coil 1520 is an equivalent circuit element of the inductors L3 and L4. The capacitor C1 shunted at the midpoint of the first coil 1510 is the first shunt capacitor 1571, and the capacitor C2 shunted at the midpoint of the second coil 1520 is the second shunt capacitor 1572. A capacitor C3 located between the ground and the first coil 1510 and the second coil 1520 is an equivalent circuit element of a balance capacitor.

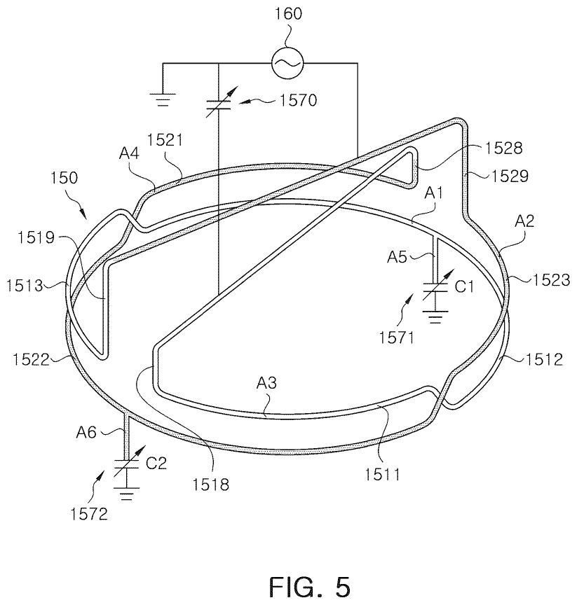

FIGS. 5 to 7 show current according to each point of the antenna member 150 according to an exemplary embodiment in the present disclosure. In FIGS. 5 to 7, reference letters A1 to A6 provided in respective positions refer to current values at the corresponding positions.

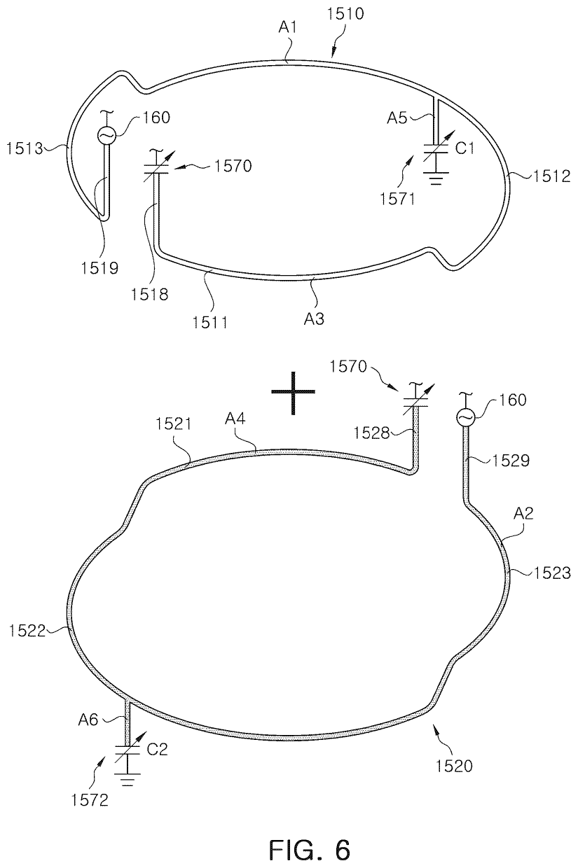

As illustrated in FIGS. 5 and 6, in each of the first coil 1510 and the second coil 1520, when a portion of the first portion from which the second portion extends, that is, a portion of the (1-1)-th portion 1511 from which the second portion 1512 extends is referred to as 0°, the first supply terminal 1519 is provided in the first portion at a position of 90° with respect to 0°, and when a portion extending from the (1-1)-th portion 1521 to the second portion 1522 is referred to as 0°, the second supply terminal 1529 is provided in the second portion at a position of 90° with respect to 0°.

The indication of the angles above 0° and 90° means that they are substantially 0° and 90° considering portions in which the height changes, but does not mean that they are mathematically exactly 0° and 90°.

The current flowing through the antenna member 150 may be adjusted before and after each of the first shunt capacitor 1571 and the second shunt capacitor 1572 according to a change in capacitance of the first shunt capacitor 1571 or the second shunt capacitor 1572.

As shown in FIGS. 5 to 7, in the antenna member 150 including the dual coil, a current flowing through the first shunt capacitors C1 and 1571 is defined as A5, a current flowing between a branch point of the first shunt capacitor 1571 and the first supply terminal 1519 is defined as A1, and a current flowing between the branch point of the first shunt capacitor 1571 and the first ground terminal 1518 is defined as A3.

In addition, a current flowing through the second shunt capacitor C2 1572 is A6, a current flowing between a branch point of the second shunt capacitor 1572 and the second supply terminal 1529 is defined as A2, and a current flowing between the branch point of the second shunt capacitor 1572 and the second ground terminal 1528 is defined as A4.

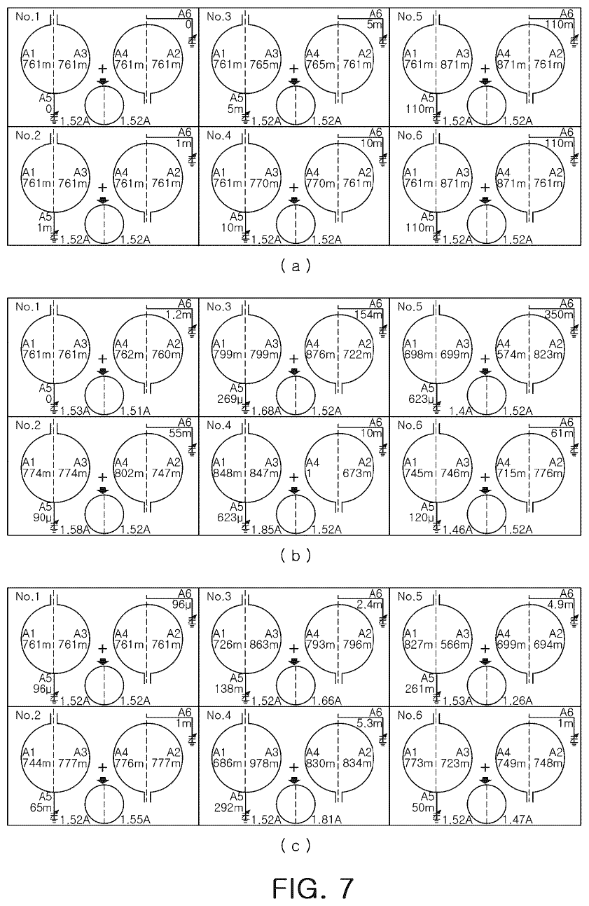

In particular, FIG. 7 is a simplified plan view of the antenna member 150 illustrated in FIGS. 5 and 6 viewed from above, in which the first coil 1510 is shown on the left, the second coil 1520 is shown on the right, and an equivalent coil obtained by adding the currents flowing through the first coil 1510 and the second coil 1520 is shown in the middle. The leftward current and rightward current of the antenna member 150 may refer to the leftward current and rightward current of the equivalent coil.

As illustrated in Table 1 below, when the values of the first shunt capacitor 1571 and the second shunt capacitor 1572 are changed at the same rate, the currents A1 to A6 are as follows.

TABLE 1

| | | | | | A1 | | A2 | | A3 | | A4 | | A5 | | A6 | |
|---|---|---|---|---|---|---|---|---|---|---|---|---|---|---|---|---|
| No. | Shunt C1 | | Shunt C2 | | (A) | | (A) | | (A) | | (A) | | (A) | | (A) | |
| 1 | 1 | p | 1 | p | 761 | m | 761 | m | 761 | m | 761 | m | 9.6 | u | 9.6 | u |
| 2 | 100 | p | 100 | p | 761 | m | 761 | m | 761 | m | 761 | m | 964 | u | 964 | u |
| 3 | 500 | p | 500 | p | 761 | m | 761 | m | 765 | m | 765 | m | 4.9 | m | 4.9 | m |
| 4 | 1 | n | 1 | n | 761 | m | 761 | m | 770 | m | 770 | m | 9.8 | m | 9.8 | m |
| 5 | 10 | n | 10 | n | 761 | m | 761 | m | 871 | m | 871 | m | 110 | m | 110 | m |
| 6 | 20 | n | 20 | n | 760 | m | 760 | m | 1.02 | | 1.02 | | 258 | m | 258 | m |

As illustrated in FIG. 7A, when calculating an equivalent current flowing in the leftward current and rightward current of the antenna member 150, 1.52 A flows in both the leftward current and the rightward current of the antenna member 150 without a change in bilateral symmetry from No. 1 to No. 6. That is, when the values of the first shunt capacitor 1571 and the second shunt capacitor 1572 are changed together, there is no change in bilateral symmetry. In addition, as illustrated in Table 2 below, when the first shunt capacitor 1571 is fixed and the value of the second shunt capacitor 1572 is changed, the currents of A1 to A6 are as follows.

TABLE 2

| | | | | | A1 | | A2 | | A3 | | A4 | | | | | |
|---|---|---|---|---|---|---|---|---|---|---|---|---|---|---|---|---|
| No. | Shunt C1 | | Shunt C2 | | (A) | | (A) | | (A) | | (A) | | A5 (A) | | A6 (A) | |
| 1 | 1 | p | 100 | p | 761 | m | 760 | m | 761 | m | 762 | m | 7.5 | u | 1.2 | m |
| 2 | 1 | p | 500 | p | 774 | m | 747 | m | 774 | m | 802 | m | 90 | u | 55 | m |
| 3 | 1 | p | 530 | p | 799 | m | 722 | m | 799 | m | 876 | m | 269 | u | 154 | m |
| 4 | 1 | p | 540 | p | 848 | m | 673 | m | 847 | m | 1 | | 623 | u | 350 | m |
| 5 | 1 | p | 560 | p; | 698 | m | 823 | m | 699 | m | 574 | m | 460 | u | 249 | m |
| 6 | 1 | p | 600 | p | 745 | m | 776 | m | 746 | m | 715 | m | 120 | u | 61 | m |

As illustrated in FIG. 7B, when calculating the equivalent current flowing through the leftward current and the rightward current of the antenna member 150, the leftward current is greater than the rightward current in Nos. 2 to 4, and the leftward current is smaller than the rightward current in Nos. 5 and 6. The rightward current is the same as 1.51 to 1.52 A in all Nos. 1 to 6. In addition, as illustrated in Table 3 below, when the second shunt capacitor 1572 is fixed and the value of the first shunt capacitor 1571 is changed, the currents of A1 to A6 are as follows.

TABLE 3

| | | | | | A1 | | A2 | | A3 | | A4 | | A5 | | A6 | |
|---|---|---|---|---|---|---|---|---|---|---|---|---|---|---|---|---|
| No. | Shunt C1 | | Shunt C2 | | (A) | | (A) | | (A) | | (A) | | (A) | | (A) | |
| 1 | 10 | p | 10 | p | 761 | m | 761 | m | 762 | m | 762 | m | 96 | u | 96 | u |
| 2 | 500 | p | 10 | p | 744 | m | 777 | m | 809 | m | 776 | m | 64.9 | m | 1.1 | m |
| 3 | 520 | p | 10 | p | 726 | m | 796 | m | 863 | m | 793 | m | 138 | m | 2.4 | m |
| 4 | 530 | p | 10 | p | 686 | m | 834 | m | 978 | m | 830 | m | 292 | m | 5.3 | m |
| 5 | 550 | p | 10 | p | 827 | m | 694 | m | 566 | m | 699 | m | 261 | m | 4.9 | m |
| 6 | 600 | p | 10 | p | 773 | m | 748 | m | 723 | m | 749 | m | 50 | m | 1 | m |

As illustrated in FIG. 7C, when calculating the equivalent current flowing through the leftward current and the rightward current of the antenna member 150, the rightward current is greater than the leftward current in Nos. 2 to 4, and the rightward current is smaller than the leftward current in Nos. 5 and 6. The leftward current is the same as 1.52 to 1.53 A in all Nos. 1 to 6. Therefore, by changing the first shunt capacitor 1571, the leftward current may be adjusted while the rightward current of the antenna member 150 is fixed, and by changing the second shunt capacitor 1572, the rightward current of the antenna member 150 may be adjusted while the leftward current thereof is fixed.

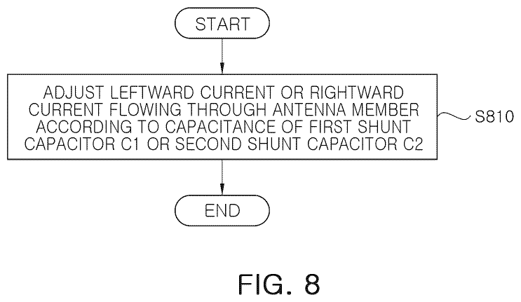

Accordingly, FIG. 8 is a flowchart illustrating a substrate treating method of the substrate treatment apparatus including the antenna member 150 according to an exemplary embodiment in the present disclosure, and as illustrated in FIG. 8, the substrate treating method in which the plasma treating apparatus 100 treats a substrate according to an exemplary embodiment of the present disclosure may include an operation (S810) of adjusting the leftward current or the rightward current flowing through the antenna member 150 according to capacitance of the first shunt capacitor 1571 or the second shunt capacitor 1572.

The operation S810 may include at least one of an operation in which a ratio of the first shunt capacitor and the second shunt capacitor is the same so that there is no change in the leftward current or the rightward current, an operation in which there is no change in the first shunt capacitor 1571, and a magnitude of capacitance of the second shunt capacitor 1572 is adjusted to be greater than a magnitude of capacitance of the first shunt capacitor 1571 to fix the rightward current and adjust only the magnitude of the leftward current, and an operation in which there is no change in the second shunt capacitor 1572, and the magnitude of capacitance of the first shunt capacitor 1571 is adjusted to be greater than the magnitude of capacitance of the second shunt capacitor 1572 to fix the leftward current and adjust only the magnitude of the rightward current.

Therefore, according to an exemplary embodiment in the present disclosure, by canceling out a potential applied to lower portions of the first coil 1510 and the second coil 1520, capacitively coupled plasma (CCP) damage applied to the window 130 may be reduced and the voltage may be distributed efficiently. Through the symmetrical arrangement of the first coil 1510 and the second coil 1520, the current flowing through the antenna member 150 may be finely adjusted, so that the uniformity of plasma may be controlled in detail.

Specifically, the current flowing through the antenna members 150 before and after the first shunt capacitor 1571 and the second shunt capacitor 1572 may be adjusted. As an example, when the first shunt capacitor 1571 and the second shunt capacitor 1572 form a neutral point at the center of the first coil 1510 and the second coil 1520, the current flowing through the left antenna member and the right antenna member between the first ground terminal 1518 and the second ground terminal 1528 or between the first supply terminal 1519 and the second supply terminal 1529, and when the first coil 1510 and the second coil 1520 are arranged at the position of the antenna member 150 illustrated in FIG. 1, a magnetic field induced by the current is formed vertically in the chamber 110 and the magnitude of the magnetic field changes according to a change in the magnitude of the current, which determines the magnitude of the magnetic field induced in the chamber 110.

That is, as illustrated in FIG. 7, by adjusting the electric field induced by adjusting the currents of the left and right antenna members, the horizontal uniformity of plasma formed in the chamber 110 may be adjusted, and in addition, the density of the entire plasma may be finely adjusted by adjusting the variable capacitor 1570.

According to various exemplary embodiments of the present disclosure, a voltage may be efficiently distributed to the antenna member, and the magnitude of the magnetic field induced in the chamber may be finely adjusted only by adjusting the shunt capacitor, thereby adjusting the electric field induced by the magnetic field and adjusting the plasma density on the left and right in the chamber.

While example exemplary embodiments have been illustrated and described above, it will be apparent to those skilled in the art that modifications and variations could be made without departing from the scope of the present disclosure as defined by the appended claims.

What is claimed is:

1. An antenna member comprising:
a first coil and a second coil that are rotationally symmetrical with each other,
wherein
the first coil includes a first supply terminal to which current is applied, a first ground terminal connected to a ground, and a first shunt capacitor shunted between the first supply terminal and the first ground terminal,
the second coil includes a second supply terminal to which current is applied, a second ground terminal connected to the ground, and a second shunt capacitor shunted between the second supply terminal and the second ground terminal,
the first coil includes an arc-shaped first portion and an arc-shaped second portion, and the first portion and the second portion form a one-turn winding as a whole,
the second coil includes an arc-shaped first portion and an arc-shaped second portion, and the first portion and the second portion form a one-turn winding as a whole,
the second portion has a height lower than a height of the first portion,
the second portion of the second coil is disposed below the first portion of the first coil, and
the second portion of the first coil is disposed below the first portion of the second coil.

2. The antenna member of claim 1, wherein the rotational symmetry is a 180° symmetry.

3. The antenna member of claim 1, wherein a center angle between the first portion and the second portion is 180°.

4. The antenna member of claim 1, wherein the first supply terminal and the second supply terminal are each provided in the first portion.

5. The antenna member of claim 1, wherein, in each of the first coil and the second coil, when a portion in which the second portion extends from the first portion is referred to as 0°, the first supply terminal and the second supply terminal are provided in the first portion in a position of 90° with respect to 0°.

6. The antenna member of claim 1, wherein the first shunt capacitor and the second shunt capacitor are each provided in the second portion.

7. The antenna member of claim 1, wherein, in each of the first coil and the second coil, when a portion in which the second portion extends from the first portion is referred to as 0°, the first shunt capacitor and the second shunt capacitor are provided in the second portion in a position of 90° with respect to 0°.

8. The antenna member of claim 1, further comprising a variable capacitor connected to each of the first ground terminal and the second ground terminal.

9. The antenna member of claim 1, wherein the first supply terminal and the first ground terminal are provided to be adjacent to each other, and the second supply terminal and the second ground terminal are provided in positions adjacent to each other.

10. The antenna member of claim 1, wherein the first shunt capacitor and the second shunt capacitor are variable capacitors.

11. A substrate treatment apparatus comprising:
a chamber providing a treatment space;
a chuck member provided in the treatment space to support a substrate;
a window disposed above the chuck member; and
an antenna member disposed above the window,
wherein the antenna member includes:
a first coil and a second coil that are rotationally symmetrical with each other,
wherein
the first coil includes a first supply terminal to which current is applied, a first ground terminal connected to a ground, and a first shunt capacitor shunted between the first supply terminal and the first ground terminal,
the second coil includes a second supply terminal to which current is applied, a second ground terminal connected to the ground, and a second shunt capacitor shunted between the second supply terminal and the second ground terminal,
the first coil includes an arc-shaped first portion and an arc-shaped second portion, and the first portion and the second portion form a one-turn winding as a whole,
the second coil includes an arc-shaped first portion and an arc-shaped second portion, and the first portion and the second portion form a one-turn winding as a whole,
the second portion has a height lower than a height of the first portion,
the second portion of the second coil is disposed below the first portion of the first coil, and
the second portion of the first coil is disposed below the first portion of the second coil.

12. The substrate treatment apparatus of claim 11, wherein the rotational symmetry is a 180° symmetry.

13. The substrate treatment apparatus of claim 11, wherein the first supply terminal and the second supply terminal are each provided in the first portion.

14. The substrate treatment apparatus of claim 11, wherein, in each of the first coil and the second coil, when a portion in which the second portion extends from the first portion is referred to as 0°, the first supply terminal and the second supply terminal are provided in the first portion in a position of 90° with respect to 0°.

15. The substrate treatment apparatus of claim 11, wherein the first shunt capacitor and the second shunt capacitor are each provided in the second portion.

16. The substrate treatment apparatus of claim 11, wherein, in each of the first coil and the second coil, when a portion in which the second portion extends from the first portion is referred to as 0°, the first shunt capacitor and the second shunt capacitor are provided in the second portion in a position of 90° with respect to 0°.

17. The substrate treatment apparatus of claim 11, wherein a variable capacitor connected to each of the first ground terminal and the second ground terminal.

18. The substrate treatment apparatus of claim 11, wherein the first shunt capacitor and the second shunt capacitor are variable capacitors.

19. The substrate treatment apparatus of claim 18, wherein the current flowing through the antenna member is adjusted before and after each of the first shunt capacitor and the second shunt capacitor, according to a change in capacitance of the first shunt capacitor or the second shunt capacitor.

20. A substrate treating method performed by the substrate treatment apparatus according to claim 11, the substrate treating method comprising:
adjusting a leftward current or a rightward current flowing through the antenna member according to capacitance of the first shunt capacitor or the second shunt capacitor,
wherein the adjusting includes at least one of:
an operation in which a ratio of the first shunt capacitor and the second shunt capacitor is the same so that there is no change in the leftward current or the rightward current;
an operation in which there is no change in the first shunt capacitor, and a magnitude of capacitance of the second shunt capacitor is adjusted to be greater than a magnitude of capacitance of the first shunt capacitor to fix the rightward current and adjust only the magnitude of the leftward current; and
an operation in which there is no change in the second shunt capacitor, and the magnitude of capacitance of the first shunt capacitor is adjusted to be greater than the magnitude of capacitance of the second shunt capacitor to fix the leftward current and adjust only the magnitude of the rightward current.
